(19) United States
(12) Patent Application Publication
(10) Pub. No.: US 2016/0027943 A1
(43) Pub. Date: Jan. 28, 2016

(54) CONCENTRATING PHOTOVOLTAIC SKYLIGHT BASED ON HOLOGRAMS AND/OR METHODS OF MAKING THE SAME

(71) Applicant: Guardian Industries Corp., Auburn Hills, MI (US)

(72) Inventors: Martin D. BRACAMONTE, Carleton, MI (US); Vijayen S. VEERASAMY, Ann Arbor, MI (US)

(21) Appl. No.: 14/341,011

(22) Filed: Jul. 25, 2014

(51) Int. Cl. H01L 31/054; G03H 1/02; H02S 20/26

(52) U.S. Cl. CPC H01L 31/054; H02S 20/26; G03H 1/0272

(57) ABSTRACT

Improved building-integrated photovoltaic (BIPV) systems according to certain example embodiments may include concentrated photovoltaic skylights or other windows in which holographic optical elements (HOEs) are provided. The HOEs are formed on or in a substantially planar glass substrate, e.g., at light coupling locations, and they help form a holographic projection of light in a desired wavelength range on a photovoltaic module. The photovoltaic module may, for example, be connected to an outer edge of the substrate in certain example embodiments. Holographically projected light may propagate through the substrate in accordance with the principles of total internal reflection (TIR), which may be somewhat lossy in some cases. A lens provided between the light source (e.g., the sun) may help re-orient the light in a desired direction so as to improve the efficiency of the HOEs.

### FIELD OF THE INVENTION

Certain example embodiments of this invention relate to improved solar photovoltaic systems for use in building-integrated photovoltaic applications, and/or methods of making the same. More particularly, certain example embodiments of this invention relate to building-integrated photovoltaic systems including concentrating photovoltaic skylights or other windows based on holograms, and/or methods of making the same.

### BACKGROUND AND SUMMARY OF EXAMPLE EMBODIMENTS OF THE INVENTION

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material generates electron-hole pairs in the active region.

Photovoltaic devices are known in the art (e.g., see U.S. Pat. Nos. 6,784,361, 6,288,325, 6,613,603, and 6,123,824, the disclosures of which are hereby incorporated herein by reference). Some conventional mainstream photovoltaic modules use a large number of crystalline silicon (c-Si) wafers. The inclusion of the large number of c-Si wafers tends to dominate the cost of the overall photovoltaic module. Indeed, about 60% of the costs involved in the production of conventional photovoltaic modules is related to the c-Si solar cells. To help address this issue, concentrated photovoltaic (CPV) systems have been proposed.

CPV systems typically use large area optical components to collect and direct sunlight, and transfer the energy onto small, high-efficiency photovoltaic (PV) cells. CPV systems have the potential for higher overall conversion efficiencies while reducing the quantity of costly, environmentally sensitive semiconductor materials, etc. Sunlight may in some instances be focused with concentration ratios of 100× to 1000×. Calculations suggest that a concentration ratio of approximately 10× should enable a photovoltaic system to be produced that uses at least 90% less silicon material.

To further improve efficiency, some CPV systems incorporate mechanical tracking to maintain alignment with the sun. System designs may take into account cell alignment tolerances, angular acceptance, flux uniformity, and/or other concerns. In this regard, it is noted that high-flux concentrators sometimes include of a large primary optical element to focus sunlight and a secondary optical element for flux homogenization. A common design approach divides the outward-facing primary optical element into several small apertures, each with its own individual secondary element and solar cell. This arrangement can help transform the overall optical volume into a thin system that can be easily assembled and mounted for two-axis tracking.

As a general principle, for CPV systems to be cost-effective, the complete cost of the optics, assembly, and mechanical tracking, generally should not exceed the cost savings gained from using small area PV cells.

Unfortunately, however, integrating hundreds of PV cells all aligned to their respective optics frequently leads to large-scale connectivity and cost concerns. Notwithstanding their obtrusive nature, these systems can be too cumbersome to integrate into windows. Thus, although there has been work concerning how to integrate solar cells into windows and glazings in a less obtrusive manner, problems persist, and it oftentimes is difficult to employ efficiency-boosting approaches in other CPV applications to building-integrated photovoltaic (BIPV) applications.

Thus, it will be appreciated there is a need in the art for improved building-integrated photovoltaic systems, and/or methods of making the same.

In certain example embodiments, a window is provided. A substantially planar glass substrate has a bulk defined by first and second major surfaces and edges substantially orthogonal to the first and second major surfaces. A photovoltaic module is provided, directly or indirectly, on one of said edges of the substrate. Holographic optical elements are provided on at least the second major surface of the substrate. The holographic optical elements are recorded and positioned so as to alter the amplitude and/or phase of light incident thereon to holographically project light of a selected wavelength range on the photovoltaic module.

In certain example embodiments, a substrate for use in a building-integrated photovoltaic (BIPV) product is provided. A bulk of the substrate is defined by first and second major surfaces and edges substantially orthogonal to the first and second major surfaces. Holographic optical elements are laser-scribed in the substrate using non-spherical wavefronts, with the holographic optical elements being recorded and positioned so as to project light of a selected wavelength range on one said edge of the substrate. At least some of the holographic optical elements holographically project the light of the selected wavelength range on the one said edge indirectly through lossy total internal reflection (TIR) through the substrate. The substrate has a visible transmission of at least 50%.

In certain example embodiments, a method of making a building-integrated photovoltaic (BIPV) product is provided. A plurality of holographic optical elements is formed in and/or on a first substantially planar glass substrate having a bulk defined by first and second major surfaces and edges substantially orthogonal to the first and second major surfaces. The holographic optical elements are provided in and/or on at least the second major surface of the first substrate, with the holographic optical elements being recorded with a line density and spacing sufficient to project light of a selected wavelength range on one of said edges of the first substrate.

Similar windows, BIPV devices, and/or other products, as well as methods of making the same, also are contemplated herein. Such products may be used, for instance, in commercial and/or residential settings.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIGS. 1A and 1B help highlight differences between lossless and lossy waveguiding;

FIG. 2 is a schematic partial perspective view of a building-integrated photovoltaic (BIPV) device in accordance with certain example embodiments;

FIG. 3 is a cross-sectional view of a BIPV device in accordance with certain example embodiments;

FIG. 4 is a cross-sectional view of another BIPV device in accordance with certain example embodiments; and

FIG. 5 is a cross-sectional view of still another BIPV device in accordance with certain example embodiments.

### DETAILED DESCRIPTION OF EXAMPLE EMBODIMENTS OF THE INVENTION

Certain example embodiments relate to an alternative approach for planar concentration by replacing multiple non-imaging secondary optics and their associated photovoltaic (PV) cells with a single multimode glass waveguide connected to a shared PV cell. Sunlight collected by each aperture of the arrayed primary optical element may, for example, be coupled into a common glass slab waveguide using spatially localized re-directing features such as holograms, prisms, gratings on surface 2, scattering features in the bulk of the glass waveguide, and/or the like.

In certain example embodiments, once scattered or diffracted, incoming rays that exceed the critical angle defined by Snell's Law propagate via total internal reflection (TIR) within the waveguide to the exit aperture, which may in certain example embodiments be provided at the edge of the slab. Because TIR is a complete reflection with negligible spectral or polarization-dependent losses, this arrangement advantageously enables long propagation lifetimes. Planar waveguides also can in some example embodiments provide excellent beam homogenization when coupling diverging illumination, e.g., into a high number of supported modes. In certain example embodiments, the waveguide may transport sunlight collected over the entire input aperture to a single PV cell placed at the waveguide edge. PV alignment with the light from the exit aperture is greatly simplified, e.g., as comparatively large cells can be connected to the waveguide edge. Moreover, certain example embodiments may provide a smaller number of PV cells, thereby reducing connection complexity, potentially allowing a reduced number of heat sinks to manage system output. For instance, a single heat sink may be provided for a single PV cell provided at one edge of a slab.

When it comes to conventional planar waveguide slabs, completely efficient waveguide coupling from multiple locations and lossless propagation can occur through a monotonic increase in modal volume. For example, light guide plates used in flat-panel display backlighting applications use tapered or stepped-thickness waveguides. The waveguide thickness grows as light is collected from each subsequent aperture, limiting the aspect ratio and therefore the maximum physical length of the concentrator. However, if the system can accept some guiding loss, planar slab waveguides that maintain the same modal cross-section can be used.

Although conventional planar slabs are at least theoretically unlimited in length, guided rays can strike a subsequent coupling region and decouple as a loss, e.g., unless there is a corresponding increase in modal volume. The number of TIR interactions during propagation to a PV cell can affect the likelihood of decoupling and therefore the optical efficiency. Couplings may be present, potentially occupying less than 0.1% of the waveguide surface, and thereby enable the system to yield both high efficiency and high concentration.

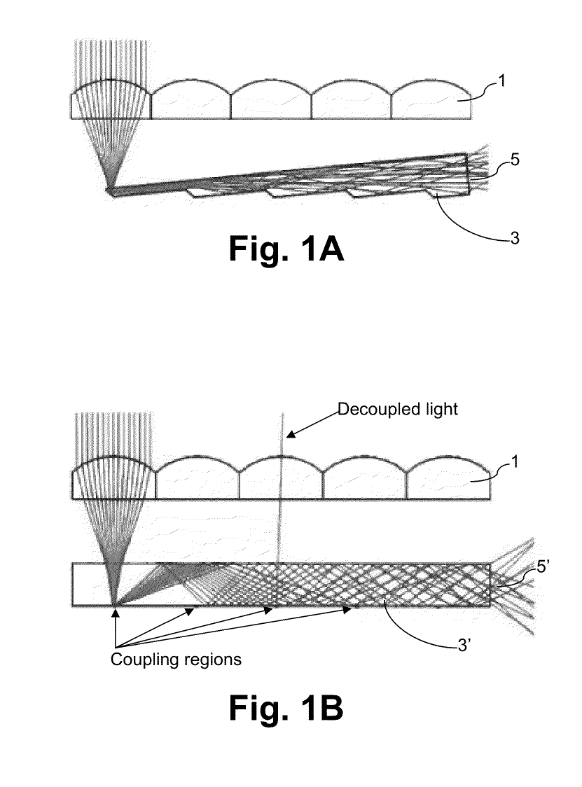

FIGS. 1A and 1B help highlight differences between lossless (e.g., limited length) and lossy (e.g., limited efficiency) waveguiding. As shown in FIG. 1A, light passes through a primary lens array 1 and into a slab 3. It can be seen from FIG. 1A that coupling without loss requires an increase in modal volume (e.g., moving from left to right) of the slab 3 towards the exit aperture 5, where a PV cell assumed to be present at the far right of the slab 3.

By contrast, as shown in FIG. 1B, light within a planar waveguide 3′ may strike subsequent coupling regions and decouple as a loss, e.g., as the light moves towards the exit aperture 5′. These coupling regions occupy only a small fraction of the planar waveguide 3′, however, and thereby enables high efficiency.

As indicated above, certain example embodiments make use of holograms. More particularly, holographic optical elements may be provided at coupling regions, e.g., on surface 1, 2, and/or in the bulk of glass comprising the waveguide. The holographic optical elements may, for example, be implemented in gratings laminated between two sheets of glass, inscribed by lasers or other suitable means into a suitable recording medium, etc.

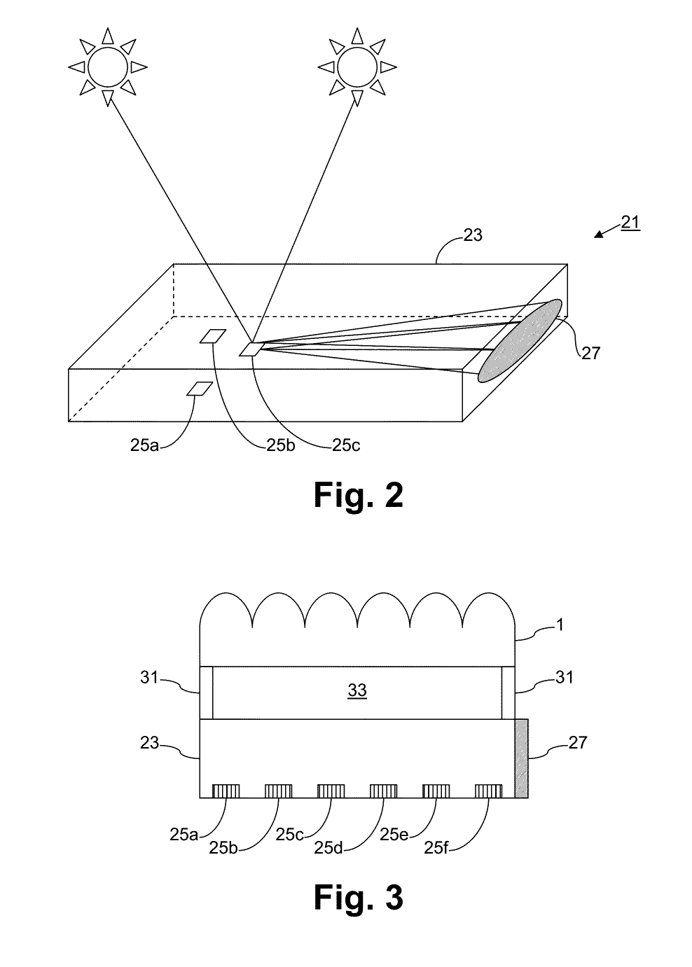

The approach taken by certain example embodiments is schematically represented by FIG. 2. More particularly, FIG. 2 is a schematic partial perspective view of a building-integrated photovoltaic (BIPV) device 21 in accordance with certain example embodiments. The sun's position is shown as changing, which may be a function of daily cycles, season, etc. Although individual secondary optics require multiple PV cells in conventional approaches, the more slab-like waveguide shown in FIG. 2 advantageously helps homogenize and transport sunlight incident thereon to a single cell. Increasing the waveguide length advantageously does not increase the required PV cell area because of TIR is used.

In FIG. 2, the device 21 includes a substrate 23 having holographic optical elements (HOEs) 25a-25c provided on a surface 2 thereof. The HOEs 25a-25c may be in the form of holographic gratings, scatterers, and/or the like. Light incident on the HOEs 25a-25c is redirected through the substrate 23, which acts as a waveguide, and a hologram is projected on the photovoltaic module 27. FIG. 2 shows the light being projected directly on the photovoltaic module 27 by the HOEs 25a-25c. It will be appreciated, however, that the HOEs 25a-25c may indirectly project the light on the photovoltaic module 27 via lossless or lossy TIR through the bulk of the substrate 21.

To achieve compactness, aspherical and/or other shaped elements (of or including plastic, for example) may be provided as diffractive physical structures in connection with the waveguide. For instance, these structures may be adhered to the waveguide, embedded in the bulk of the waveguide, provided as a separate structure connected to a carrier substrate, etc.

Volume holographic elements may be used, as well. Volume holograms are holograms where the thickness of the recording material is much larger than the light wavelength(s) used for recording, and volume holograms function on the principle of Bragg diffraction. Volume holographic elements may be implemented as thick phase gratings, e.g., produced by interference fringes in a relatively thick emulsion (e.g., from 5-30 microns thick) such as, for example, dichromated gelatin (DCG).

In certain example embodiments, one or both major surfaces of the glass may be laser etched or otherwise patterned to form HOEs with a desired pattern. The grooves may be filled with a polymer, silicon, amide, imide, glymo, and/or other inclusive material having a desired refractive index, e.g., to smooth out the surface after patterning. In certain example embodiments, a separate grating having such features may be provided and may, for example, be sandwiched between first and second glass substrates or the like.

Photo-thermo-refractive (PTR) glass has emerged as another holographic material and is less “messy” that an emulsion. The properties of PTR glass have allowed for the recording of volume holograms, e.g., with 98% of diffraction efficiency in a 1 mm thick glass plate, with photosensitivity restricted to the UV region. Certain example embodiments of this invention relate to techniques for hologram recording and reconstruction that allow for the design and implementation of HOEs in PTR glass for playback in the visible and/or the infrared (IR) regions of the light spectra. PTR glass may comprise, for example, a majority of sodium and silica. PTR materials used in PTR glass may include one or more transition metals and/or oxides thereof, generally. Specific examples of PTR materials include iodates, niobates, silver, iron, and/or the like. The PTR materials may crystallize to create the desired features, e.g., when activated or scribed with a laser or other means. Unlike classical HOE design where the phase profile is generated as the interference of two spherical wavefronts, non-spherical wavefronts may be employed in the construction of the HOEs formed in PTR glass.

FIG. 3 is a cross-sectional view of a BIPV device in accordance with certain example embodiments. FIG. 3 is similar to FIG. 2 in that it includes a waveguide substrate 23 in or on which a plurality of HOEs 25a-25f are formed. The HOEs 25a-25f are recorded and positioned relative to one another and/or the photovoltaic module 27 so as to alter the amplitude and/or phase of light incident thereon to holographically project light of a selected wavelength range on the photovoltaic module 27. In certain example embodiments, the HOEs 25a-25f may be formed to have a density on the order of 100 lines per millimeter and/or may be spaced apart by no more than a few centimeters to on the order of 10s of centimeters. It will be appreciated that the density of the lines may be balanced with their spacing, e.g., to create the desired holographic projection while providing a desired visible transmission through the device. Visible transmission may be at least about 50%, more preferably at least about 55%, and potentially even higher. For instance, when the substrate 23 is formed from a low-iron glass, very high visible transmissions (e.g., at least about 80%, more preferably at least about 85%, still more preferably at least about 90%, and sometimes as high as 95% or higher). This may be achieved by providing HOEs over less than 10% of the area of a major surface, more preferably less than 5%, and sometimes less than 1%.

The HOEs 25a-25f may be formed in photo-thermo-refractive (PTR) glass, e.g., using non-spherical wavefronts. At least some of the HOEs 25a-25f may holographically project the light of the selected wavelength range on the photovoltaic module 27 indirectly through the substrate 23, e.g., using lossy TIR. It is noted, however, that some of the HOEs 25a-25f may holographically project the light of the selected wavelength range directly on the photovoltaic module 27. The TIR may be lossy, e.g., so that at most 10% of the flux in the desired wavelength range is lost, more preferably at most 5% is lost, still more preferably at most 3% is lost, and sometimes only 1-2% is lost.

Alternatively, or in addition, the HOEs 25a-25f may be formed by laser-scribing or otherwise forming patterns in the surface of the substrate 23. The patterns may have a coating wet-applied thereon that is subsequently cured, e.g., to smooth out the surface and protect the underlying patterns. The materials are as noted above.

The selected wavelength range may encompass at least portions of the infrared and/or visible spectra. For example, as is known, certain semiconductor materials used in solar cells respond well to IR radiation. Thus, near infrared (NIR) and/or other spectra may be projected on the photovoltaic module 27 in certain example embodiments. In cases where IR radiation is projected on the photovoltaic module 27, it may be desirable to provide a heat sink proximate to the photovoltaic module 27, e.g., to aid in cooling it. Of course, a heat sink may be provided regardless of whether IR radiation is projected on the photovoltaic module 27.

As shown in FIG. 3, a lens 1 is spaced apart from the substrate 23. The lens 1 is shaped and arranged to alter the wavefront profile and/or beam direction of light incident thereon so that light incident on the HOEs 25a-25f has a desired wavefront profile and/or beam direction. The lens 1 and the substrate 23 are maintained in substantially parallel spaced apart relation using a spacer system 31 or the like, and a gap or cavity 33 is defined between the lens 1 and the substrate 23. The lens 1 may be a positive lens (e.g., a lens where the center portions are thicker than the outer portions). A series of plano-convex lenses in an array are shown in FIG. 3. However, different example embodiments may incorporate a single plano-convex lens, a single convexoconvex lens, an array of convexoconvex lenses, and/or the like. The lens 1 may be formed of glass having the same or different composition as the substrate 23. For example, the lens 1 may be a low-iron glass, as well.

To help reduce the amount of cooling and/or to avoid projecting unhelpful wavelengths onto the photovoltaic module 27, the selected wavelength range may encompass at least a substantial portion of the visible spectrum but may exclude at least a substantial portion of the infrared spectrum.

The photovoltaic module 27 may include any suitable solar cell. For example, a CIS/CIGS type solar cell, a-Si, c-Si, and/or other solar cell may be provided in different example embodiments.

Certain example embodiments may provide concentration ratios of up to about 100×. To balance visible transmission, manufacturing ease, etc., concentration rations of 3×-20× may be preferred in some cases. In certain example embodiments, low concentration values may be desired (e.g., less than 10×, less than 5×, less than 3×, etc.), e.g., for cost considerations.

It is noted that certain example embodiments may provide only a substrate with HOEs formed therein and/or thereon. In such cases, a temporary protective sheet may be provided thereon, e.g., to facilitate on-site processing and/or handling, shipping (e.g., to a fabricator who might heat treat (thermally temper or heat strengthen) the substrate, connect a PV module, built it into a BIPV product, etc.), handling, storage, etc.

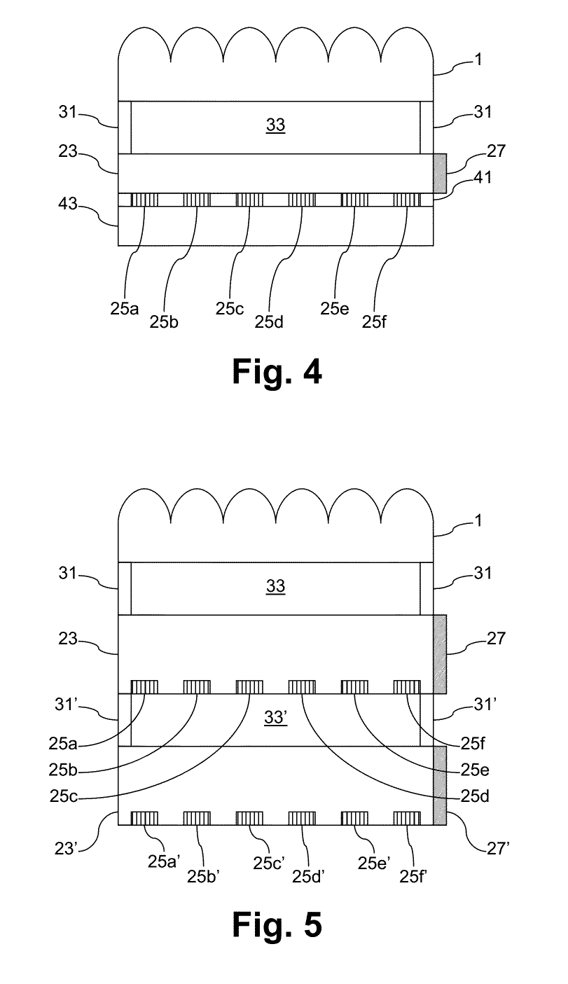

FIG. 4 is a cross-sectional view of another BIPV device in accordance with certain example embodiments. FIG. 4 is similar to FIG. 3. However, the HOEs 25a-25f in FIG. 4 are formed in a grating 41 provided on the second surface of the substrate 23, and a second substrate 43 helps encapsulate the grating 41. In other words, in the FIG. 4 example, the grating 41 is sandwiched between the first and second substrates 31 and 43. The first and second substrates 31 and 43 may be bonded together using a laminating material such as, for example, PVB, EVA, PET, PMMA, PU, and/or the like. OptiBond or the like also may be provided in certain example embodiments. The principle of operation is the same as between FIGS. 3 and 4, e.g., in that the HOEs 25a-25f project an image onto the photovoltaic module 27, directly and/or indirectly via TIR through the first substrate 31.

It will be appreciated that multiple slabs may be provided in different example embodiments, and in some cases, each slab may project a different hologram onto a different PV module, e.g., to target different respective wavelength ranges. FIG. 5 is a cross-sectional view of another BIPV device in accordance with certain example embodiments. FIG. 5 is similar to FIG. 3, except that two waveguide slabs are provided. The top portion of FIG. 5 is the same as what is shown in FIG. 3. The bottom portion, however, includes a second substrate 23′ separated from the first substrate 23 by a second spacer system 31′, with a second gap or cavity 33′ being defined between the first and second substrates 23 and 23′. The HOEs 25a′-25f help guide holographically projected light to the second photovoltaic module 27′. It is noted that the first and second photovoltaic modules 27 and 27′ may be the same or different, e.g., based on the lighted projected thereon. In a similar vein, the HOEs 25a-25f provided to the first substrate 23 and the HOEs 25a′-25f may be the same or different, e.g., to target different respective wavelength ranges. It is noted that although FIG. 5 shows HOEs embedded in the substrates 23 and 23′, one or more separate grating may be used in place of these arrangements, e.g., so that a two-grating embodiment is provided, so that a one grating and one waveguide slab with HOEs formed therein is provided, etc.

It will be appreciated that the gaps or cavities may be at least partially filled with an inert gas such as, for example, Ar, Kr, Xe, and/or the like, e.g., to provide an insulating glass (IG) unit with improved insulating properties. The inert gas may be mixed with oxygen and/or the like in certain example embodiments.

As indicated above, certain example embodiments may include low-iron glass. The total amount of iron present is expressed herein in terms of Fe₂O₃ in accordance with standard practice. However, typically, not all iron is in the form of Fe₂O₃. Instead, iron is usually present in both the ferrous state (Fe²⁺; expressed herein as FeO, even though all ferrous state iron in the glass may not be in the form of FeO) and the ferric state (Fe³⁺). Iron in the ferrous state (Fe²⁺; FeO) is a blue-green colorant, while iron in the ferric state (Fe³⁺) is a yellow-green colorant. The blue-green colorant of ferrous iron (Fe²⁺; FeO) is of particular concern when seeking to achieve a fairly clear or neutral colored glass, since as a strong colorant it introduces significant color into the glass. While iron in the ferric state (Fe³⁺) is also a colorant, it is of less concern when seeking to achieve a glass fairly clear in color since iron in the ferric state tends to be weaker as a colorant than its ferrous state counterpart.

In certain example embodiments of this invention, a glass is made so as to be highly transmissive to visible light, to be fairly clear or neutral in color, and to consistently realize high % TS values. High % TS values are particularly desirable for photovoltaic device applications in that high % TS values of the light-incident-side glass substrate permit such photovoltaic devices to generate more electrical energy from incident radiation since more radiation is permitted to reach the semiconductor absorbing film of the device. It has been found that the use of an extremely high batch redox in the glass manufacturing process permits resulting low-ferrous glasses made via the float process to consistently realize a desirable combination of high visible transmission, substantially neutral color, and high total solar (% TS) values. Moreover, in certain example embodiments of this invention, this technique permits these desirable features to be achieved with the use of little or no cerium oxide.

In certain example embodiments of this invention, a soda-lime-silica based glass is made using the float process with an extremely high batch redox. An example batch redox which may be used in making glasses according to certain example embodiments of this invention is from about +26 to +40, more preferably from about +27 to +35, and most preferably from about +28 to +33 (note that these are extremely high batch redox values not typically used in making glass). In making the glass via the float process or the like, the high batch redox value tends to reduce or eliminate the presence of ferrous iron (Fe²⁺; FeO) in the resulting glass, thereby permitting the glass to have a higher % TS transmission value which may be beneficial in photovoltaic applications. This is advantageous, for example, in that it permits high transmission, neutral color, high % TS glass to be made using raw materials having typical amounts of iron in certain example instances (e.g., from about 0.04 to 0.10% total iron). In certain example embodiments of this invention, the glass has a total iron content (Fe₂O₃) of no more than about 0.1%, more preferably from about 0 (or 0.04) to 0.1%, even more preferably from about 0.01 (or 0.04) to 0.08%, and most preferably from about 0.03 (or 0.04) to 0.07%. In certain example embodiments of this invention, the resulting glass may have a % FeO (ferrous iron) of from 0 to 0.0050%, more preferably from 0 to 0.0040, even more preferably from 0 to 0.0030, still more preferably from 0 to 0.0020, and most preferably from 0 to 0.0010, and possibly from 0.0005 to 0.0010 in certain example instances. In certain example embodiments, the resulting glass has a glass redox (different than batch redox) of no greater than 0.08, more preferably no greater than 0.06, still more preferably no greater than 0.04, and even more preferably no greater than 0.03 or 0.02.

In certain example embodiments, the glass substrate may have fairly clear color that may be slightly yellowish (a positive b* value is indicative of yellowish color), in addition to high visible transmission and high % TS. For example, in certain example embodiments, the glass substrate may be characterized by a visible transmission of at least about 90% (more preferably at least about 91%), a total solar (% TS) value of at least about 90% (more preferably at least about 91%), a transmissive a* color value of from −1.0 to +1.0 (more preferably from −0.5 to +0.5, even more preferably from −0.35 to 0), and a transmissive b* color value of from −0.5 to +1.5 (more preferably from 0 to +1.0, and most preferably from +0.2 to +0.8). These properties may be realized at an example non-limiting reference glass thickness of about 4 mm.

In certain example embodiments of this invention, there is provided a method of making glass comprising:

| Ingredient | wt. % |
|---|---|
| SiO₂ | 67-75% |
| Na₂O | 10-20% |
| CaO | 5-15% |
| total iron (expressed as Fe₂O₃) | 0.001 to 0.1% |
| % FeO | 0 to 0.005 |

wherein the glass has visible transmission of at least about 90%, a transmissive a* color value of −1.0 to +1.0, a transmissive b* color value of from −0.50 to +1.5, % TS of at least 89.5%, and wherein the method comprises using a batch redox of from +26 to +40 in making the glass.

In certain example embodiments of this invention, there is provided a glass comprising:

| Ingredient | wt. % |
|---|---|
| SiO₂ | 67-75% |
| Na₂O | 10-20% |
| CaO | 5-15% |
| total iron (expressed as Fe₂O₃) | <=0.1% |
| % FeO | <=0.005 |
| glass redox | <=0.08 |
| antimony oxide | 0 to less than 0.01% |
| cerium oxide | 0 to 0.07% |

wherein the glass has visible transmission of at least 90%, TS transmission of at least 90%; a transmissive a* color value of −1.0 to +1.0, a transmissive b* color value of from −0.5 to +1.5.

In still further example embodiments of this invention, there is provided solar cell comprising: a glass substrate; first and second conductive layers with at least a photoelectric film provided therebetween; wherein the glass substrate is of a composition comprising:

| Ingredient | wt. % |
|---|---|
| SiO₂ | 67-75% |
| Na₂O | 10-20% |
| CaO | 5-15% |
| total iron (expressed as Fe₂O₃) | <=0.1% |
| % FeO | <=0.005 |
| glass redox | <=0.08 |
| antimony oxide | 0 to less than 0.01% |
| cerium oxide | 0 to 0.07% |

wherein the glass substrate has visible transmission of at least 90%, TS transmission of at least 90%; a transmissive a* color value of −1.0 to +1.0, a transmissive b* color value of from −0.5 to +1.5.

Although certain example embodiments are described as being laser etched, it will be appreciated that any suitable technique for recording a holographic pattern therein may be implemented. Ion beam milling, for example, may be used. Example ion sources are disclosed, for example, in U.S. Pat. Nos. 7,872,422; 7,488,951; 7,030,390; 6,988,463; 6,987,364; 6,815,690; 6,812,648; 6,359,388; and Re. 38,358; the disclosures of each of which are hereby incorporated herein by reference.

The substrates described herein may be heat treated (e.g., heat strengthened and/or thermally tempered), and/or chemically tempered, in certain example embodiments. The terms “heat treatment” and “heat treating” as used herein mean heating the article to a temperature sufficient to achieve thermal tempering and/or heat strengthening of the glass inclusive article. This definition includes, for example, heating a coated article in an oven or furnace at a temperature of at least about 550 degrees C., more preferably at least about 580 degrees C., more preferably at least about 600 degrees C., more preferably at least about 620 degrees C., and most preferably at least about 650 degrees C. for a sufficient period to allow tempering and/or heat strengthening. This may be for at least about two minutes, or up to about 10 minutes, in certain example embodiments.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

In certain example embodiments, a window is provided. A substantially planar glass substrate has a bulk defined by first and second major surfaces and edges substantially orthogonal to the first and second major surfaces. A photovoltaic module is provided, directly or indirectly, on one of said edges of the substrate. A plurality of holographic optical elements is provided on at least the second major surface of the substrate, with the holographic optical elements being recorded and positioned so as to alter the amplitude and/or phase of light incident thereon to holographically project light of a selected wavelength range on the photovoltaic module.

In addition to the features of the previous paragraph, in certain example embodiments, the substrate may be a photo-thermo-refractive (PTR) glass substrate.

In addition to the features of the previous paragraph, in certain example embodiments, the holographic optical elements may be recorded in the PTR glass substrate using non-spherical wavefronts.

In addition to the features of any of the three previous paragraphs, in certain example embodiments, at least some of the holographic optical elements may holographically project the light of the selected wavelength range on the photovoltaic module directly, whereas the other holographic optical elements may holographically project the light of the selected wavelength range on the photovoltaic module indirectly, e.g., through total internal reflection (TIR) through the substrate.

In addition to the features of the previous paragraph, in certain example embodiments, the TIR may be lossy.

In addition to the features of any of the five previous paragraphs, in certain example embodiments, the selected wavelength range may encompass at least portions of the infrared and visible spectra.

In addition to the features of the previous paragraph, in certain example embodiments, a heat sink may be provided proximate to the photovoltaic module, with the heat sink being configured to cool the photovoltaic module.

In addition to the features of any of the seven previous paragraphs, in certain example embodiments, the selected wavelength range may encompass at least a substantial portion of the visible spectrum and may exclude at least a substantial portion of the infrared spectrum.

In addition to the features of any of the eight previous paragraphs, in certain example embodiments, a lens may be spaced apart from the substrate, with the lens optionally being shaped and arranged to alter the wavefront profile and/or beam direction of light incident thereon, e.g., so that light incident on the holographic optical elements has a desired wavefront profile and/or beam direction.

In addition to the features of the previous paragraph, in certain example embodiments, the lens may be a positive lens.

In addition to the features of either of the two previous paragraphs, in certain example embodiments, the second major surface of the substrate may be laser etched to form the holographic optical elements, with each said holographic optical element optionally having a density on the order of 100 lines per millimeter and/or being spaced apart by no more than 10s of centimeters.

In addition to the features of the previous paragraph, in certain example embodiments, a cured wet-applied coating may be provided over the holographic optical elements.

In addition to the features of any of the 12 previous paragraphs, in certain example embodiments, there may be a grating in which the holographic optical elements are located, with the grating optionally being provided on the second major surface of the substrate.

In addition to the features of the previous paragraph, in certain example embodiments, a second substrate may be provided, with the grating optionally being sandwiched by the substrate and the second substrate.

In addition to the features of the previous paragraph, in certain example embodiments, the substrate, the grating, and the second substrate may be laminated together.

In addition to the features of any of the 15 previous paragraphs, in certain example embodiments, the holographic optical elements may provide a concentration ratio of 3×-20×.

In addition to the features of any of the 16 previous paragraphs, in certain example embodiments, the holographic optical elements may provide a concentration ratio of less than 5×.

In addition to the features of any of the 17 previous paragraphs, in certain example embodiments, the window may be a skylight that has a visible transmission of at least 50%.

In certain example embodiments, a substrate for use in a building-integrated photovoltaic (BIPV) product is provided. The substrate includes a bulk defined by first and second major surfaces and edges substantially orthogonal to the first and second major surfaces. A plurality of holographic optical elements is laser-scribed in the substrate using non-spherical wavefronts, with the holographic optical elements being recorded and positioned so as to project light of a selected wavelength range on one said edge of the substrate. At least some of the holographic optical elements holographically project the light of the selected wavelength range on the one said edge indirectly through lossy total internal reflection (TIR) through the substrate. The substrate has a visible transmission of at least 50%.

In certain example embodiments, a method of making a building-integrated photovoltaic (BIPV) product is provided. A plurality of holographic optical elements is formed in and/or on a first substantially planar glass substrate having a bulk defined by first and second major surfaces and edges substantially orthogonal to the first and second major surfaces. The holographic optical elements are provided in and/or on at least the second major surface of the first substrate, with the holographic optical elements being recorded with a line density and spacing sufficient to project light of a selected wavelength range on one of said edges of the first substrate.

In addition to the features of the previous paragraph, in certain example embodiments, a photovoltaic module may be connected, directly or indirectly, to the one of said edge of the first substrate.

In addition to the features of the previous paragraph, in certain example embodiments, the first substrate may be a photo-thermo-refractive (PTR) glass substrate and the holographic optical elements optionally may be laser-scribed in at least the second surface of the PTR glass substrate, e.g., using non-spherical wavefronts.

In addition to the features of any of the three previous paragraphs, in certain example embodiments, at least some of the holographic optical elements may holographically project the light of the selected wavelength range on the one said edge of the first substrate indirectly, e.g., through lossy total internal reflection (TIR) through the first substrate.

In addition to the features of any of the four previous paragraphs, in certain example embodiments, the selected wavelength range may encompass at least portions of the infrared and visible spectra.

In addition to the features of any of the five previous paragraphs, in certain example embodiments, the selected wavelength range may encompass at least a substantial portion of the visible spectrum and may exclude at least a substantial portion of the infrared spectrum.

In addition to the features of any of the five previous paragraphs, in certain example embodiments, a lens may be spaced apart from the first substrate, with the lens optionally being shaped and arranged to alter the wavefront profile and/or beam direction of light incident thereon, e.g., so that light incident on the holographic optical elements has a desired wavefront profile and/or beam direction.

In addition to the features of any of the six previous paragraphs, in certain example embodiments, there may be a grating in which the holographic optical elements are located, with the grating optionally being provided on the second major surface of the first substrate.

In addition to the features of the previous paragraph, in certain example embodiments, a second substrate may be provided, e.g., with the grating being sandwiched by the first substrate and the second substrate.

In addition to the features of the previous paragraph, in certain example embodiments, the first and second substrates may be laminated together with the grating therebetween.

In addition to the features of any of the four previous paragraphs, in certain example embodiments, a temporary protective sheet may be provided over the first substrate.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A window, comprising:
a substantially planar glass substrate having a bulk defined by first and second major surfaces and edges substantially orthogonal to the first and second major surfaces;
a photovoltaic module provided, directly or indirectly, on one of said edges of the substrate; and
a plurality of holographic optical elements provided on at least the second major surface of the substrate, the holographic optical elements being recorded and positioned so as to alter the amplitude and/or phase of light incident thereon to holographically project light of a selected wavelength range on the photovoltaic module.

2. The window of claim 1, wherein the substrate is a photo-thermo-refractive (PTR) glass substrate.

3. The window of claim 2, wherein the holographic optical elements are recorded in the PTR glass substrate using non-spherical wavefronts.

4. The window of claim 1, wherein at least some of the holographic optical elements holographically project the light of the selected wavelength range on the photovoltaic module directly, whereas the other holographic optical elements holographically project the light of the selected wavelength range on the photovoltaic module indirectly through total internal reflection (TIR) through the substrate.

5. The window of claim 4, wherein the TIR 15 lossy.

6. The window of claim 1, wherein the selected wavelength range encompasses at least portions of the infrared and visible spectra.

7. The window of claim 6, further comprising a heat sink proximate to the photovoltaic module, the heat sink being configured to cool the photovoltaic module.

8. The window of claim 1, wherein the selected wavelength range encompasses at least a substantial portion of the visible spectrum and excludes at least a substantial portion of the infrared spectrum.

9. The window of claim 1, further comprising a lens spaced apart from the substrate, the lens being shaped and arranged to alter the wavefront profile and/or beam direction of light incident thereon so that light incident on the holographic optical elements has a desired wavefront profile and/or beam direction.

10. The window of claim 9, wherein the lens is a positive lens.

11. The window of claim 9, wherein the second major surface of the substrate is laser etched to form the holographic optical elements, each said holographic optical element having a density on the order of 100 lines per millimeter and being spaced apart by no more than 10s of centimeters.

12. The window of claim 11, further comprising a cured wet-applied coating provided over the holographic optical elements.

13. The window of claim 1, further comprising a grating in which the holographic optical elements are located, the grating being provided on the second major surface of the substrate.

14. The window of claim 13, further comprising a second substrate, the grating being sandwiched by the substrate and the second substrate.

15. The window of claim 14, wherein the substrate, the grating, and the second substrate are laminated together.

16. The window of claim 1, wherein the holographic optical elements provide a concentration ratio of 3×-20×.

17. The window of claim 1, wherein the holographic optical elements provide a concentration ratio of less than 5×.

18. The window of claim 1, wherein the window is a skylight that has a visible transmission of at least 50%.

19. A substrate for use in a building-integrated photovoltaic (BIPV) product, comprising:
a bulk defined by first and second major surfaces and edges substantially orthogonal to the first and second major surfaces; and
a plurality of holographic optical elements laser-scribed in the substrate using non-spherical wavefronts, the holographic optical elements being recorded and positioned so as to project light of a selected wavelength range on one said edge of the substrate,
wherein at least some of the holographic optical elements holographically project the light of the selected wavelength range on the one said edge indirectly through lossy total internal reflection (TIR) through the substrate, and
wherein the substrate has a visible transmission of at least 50%.

20. A method of making a building-integrated photovoltaic (BIPV) product, the method comprising:
forming a plurality of holographic optical elements in and/or on a first substantially planar glass substrate having a bulk defined by first and second major surfaces and edges substantially orthogonal to the first and second major surfaces,
wherein the holographic optical elements are provided in and/or on at least the second major surface of the first substrate, the holographic optical elements being recorded with a line density and spacing sufficient to project light of a selected wavelength range on one of said edges of the first substrate.

21. The method of claim 20, further comprising connecting a photovoltaic module, directly or indirectly, to the one of said edge of the first substrate.

22. The method of claim 21, wherein the first substrate is a photo-thermo-refractive (PTR) glass substrate and the holographic optical elements are laser-scribed in at least the second surface of the PTR glass substrate using non-spherical wavefronts.

23. The method of claim 20, wherein at least some of the holographic optical elements holographically project the light of the selected wavelength range on the one said edge of the first substrate indirectly through lossy total internal reflection (TIR) through the first substrate.

24. The method of claim 20, wherein the selected wavelength range encompasses at least portions of the infrared and visible spectra.

25. The method of claim 20, wherein the selected wavelength range encompasses at least a substantial portion of the visible spectrum and excludes at least a substantial portion of the infrared spectrum.

26. The method of claim 21, further comprising providing a lens spaced apart from the first substrate, the lens being shaped and arranged to alter the wavefront profile and/or beam direction of light incident thereon so that light incident on the holographic optical elements has a desired wavefront profile and/or beam direction.

27. The method of claim 21, further comprising providing a grating in which the holographic optical elements are located, the grating being provided on the second major surface of the first substrate.

28. The method of claim 27, further comprising providing a second substrate, the grating being sandwiched by the first substrate and the second substrate.

29. The method of claim 28, further comprising laminating together the first and second substrates with the grating therebetween.

30. The method of claim 20, further comprising providing a temporary protective sheet over the first substrate.
